(19) United States
(12) Patent Application Publication
(10) Pub. No.: US 2007/0126606 A1
(43) Pub. Date: Jun. 7, 2007

(54) Keypad module

(75) Inventor: Chiung-Hsien Wu, Taipei (TW)

Correspondence Address: BIRCH STEWART KOLASCH & BIRCH, PO BOX 747, FALLS CHURCH, VA, 22040-0747, US

(73) Assignee: Inventec Appliances Corp.

(21) Appl. No.: 11/585,844

(22) Filed: Oct. 25, 2006

(30) Foreign Application Priority Data
Oct. 26, 2005 (TW) 94218483

(51) Int. Cl. H03M 11/00; H04M 1/00; H03K 17/94

(52) U.S. Cl. 341/22; 455/550.1

(57) ABSTRACT

A keypad module comprises a plurality of keys, receivers, and props. Each of the keys has a first pressing region and a second pressing region on an exposed surface thereof. A first receiver is disposed under the first pressing region for generating a first signal while the first pressing region is pressed, and the second receiver is disposed under the second pressing region for generating a second signal while the second receiver region is pressed. The prop is disposed between the first receiver and the second receiver for ensuring only one pressing region is pressed at a time.

### FIELD OF THE INVENTION

The present invention generally relates to a keypad module, more particularly to a keypad module applied to a portable electronic device.

### DESCRIPTION OF THE PRIOR ART

Portable electronic devices are popular nowadays. The tendency of electronic devices includes slimness in thickness, diversity in function, and so on. That is to squeeze more functions into a slim accommodation space.

As the functions become versatile in the electronic devices, the human interfaces become also more complex than usual. For instance, most mobile phones and personal digital assistants (PDA) have a function of internet connecting, through which users may send and receive emails, and furthermore may chat with friends. Definitely, additional input interfaces are needed to cooperate with electronic devices mentioned above, such that those additional functions can then be operated easily.

Refer to FIG. 1, which illustrates a schematic diagram of a PDA of prior art. The PDA 1 includes a display panel 11 and a keypad 12 with a plurality of keys 121. The plurality of keys 121 are arranged as a keyboard for computers. Such a crowded arrangement is designed for at least 26 letters of English alphabets. However, this design of keypad 12 is not convenient for users, especially for users with bigger fingers that usually import error data by mis-pressing neighboring keys.

Please refer to FIG. 2A, which illustrates a schematic diagram of a mobile phone of prior art. The mobile phone 2 comprises a touch panel 21, a keypad 22 and a touch pen 23. A user may dial phone numbers through pressing the keypad 22. However, if a user needs to edit documents such as emails or messages, he/she may choose an edit mode of the mobile phone 2, and the touch panel 21 will display a frame 21b as shown in FIG. 2B. The user can choose letters of the frame 21 b through his/her fingers or the touch pen 23, and the other region of the touch panel 21 may show the chosen letters that the user has chosen 21 a.

Through electronic devices with the touch panels, the mis-pressing problem mentioned earlier can be solved effectively. However, most of users choose electronic devices by pondering between their demands and their economic abilities because the electronic device having a touch panel costs definitely much more than the others. Therefore, improvement in reducing the cost the keypad structure shall be necessary

### SUMMARY OF THE INVENTION

The present invention is related to a keypad module, which comprises a plurality of keys, receivers, and props. Each of the keys has a first pressing region and a second pressing region on an exposed surface thereof. A first receiver is disposed under the first pressing region for generating a first signal while the first pressing region is pressed, and the second receiver is disposed under the second pressing region for generating a second signal while the second receiver region is pressed. The prop is disposed between the first receiver and the second receiver for ensuring only one pressing region is pressed at a time.

Therefore, the keypad module with a dual-mode function that the present invention disclosed herein is suitable to be applied to electronic devices. Not only the size of the keypad is reduced, but also the cost of the keypad is reduced by comparing with the conventional electronic device having a touch pad.

All the spirits and scope of the present invention will be understood by the detail and illustration described in following.

### BRIEF DESCRIPTION OF THE DRAWINGS

Other features and advantages of this invention will become more apparent in the following detailed description of the preferred embodiments of this invention, with reference to the accompanying drawings, in which:

FIG. 1 illustrates an schematic diagram of a PDA of prior art;

FIG. 2A˜FIG. 2B illustrate schematic diagrams of a mobile phone of another prior art;

FIG. 3 illustrates a schematic cross section view of a preferred keypad module in accordance with the present invention; and

FIG. 4 illustrates a schematic diagram of a PDA or a mobile phone applied with the keypad module of FIG. 3.

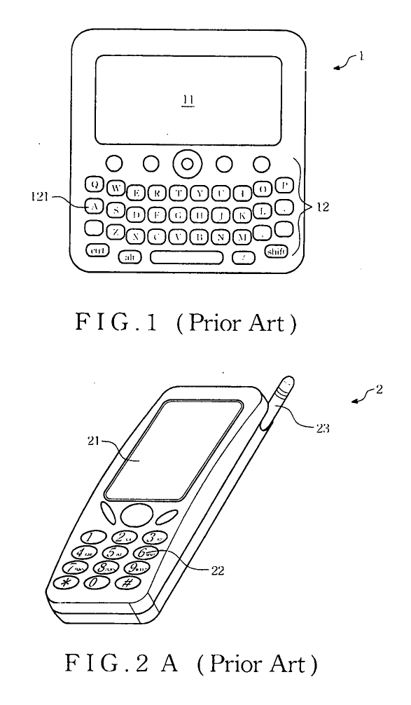

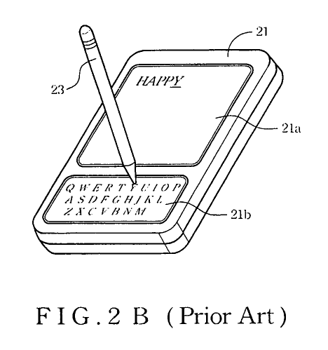

### DESCRIPTION OF THE PREFERRED EMBODIMENT

Please refer to FIG. 3, which illustrates a schematic diagram of a preferred keypad module in accordance with the present invention. The keypad module 3 comprises a key 31, a first receiver 32, a second receiver 33 and a prop 34. The exposed surface of the key 31 is divided into two regions, a first pressing region 311 and a second pressing region 312. These two pressing regions 311 and 312 are arranged symmetric to each other. As shown for example in FIG.3, the symmetric model herein for the pressing regions 311 and 312 is a left-right symmetric model but it also can be other orientation.

The first receiver 32 is disposed under the first pressing region 311 for generating a first signal while the first pressing region 311 is pressed. The second receiver 33 is disposed under the second pressing region 312 for generating a first signal while the second pressing region 312 is pressed. The first signal and the second signal are to represent the letters or symbols on the first pressing region 311 and the second pressing region 312, respectively. While the keypad 3 is assembled onto an electronic device 4, the first signal and the second signal are transmitted to the electronic device 4 for further keypad control.

The prop 34 is disposed between the first receiver 32 and the second receiver 33 to form a T shape with the key 31. Upon such an arrangement, the key 31 can play a seesaw motion with respect to the central prop 34. The prop 34 is designed for ensuring only one pressing region is pressed at a time while the key 31 is pressed. The user can only choose to import the letter on the first pressing region 311 or the letter on the second pressing region 312.

The material of the receivers 32 and 33 can be an elastomer; for instance, a rubber material. The mode that how the receiver is connected to the key pad is not restricted herein, yet it depends on the kind of the electronic device. Moreover, the material of the prop is a material with substantial rigidity. For instance, a plastic material is suitable to be adopted in an electronic device for reducing the gross weight.

The present invention provides a keypad module with a dual import mode. Applying the keypad of the present invention to an electronic device generally has advantages in decreasing numbers and sizes of keys.

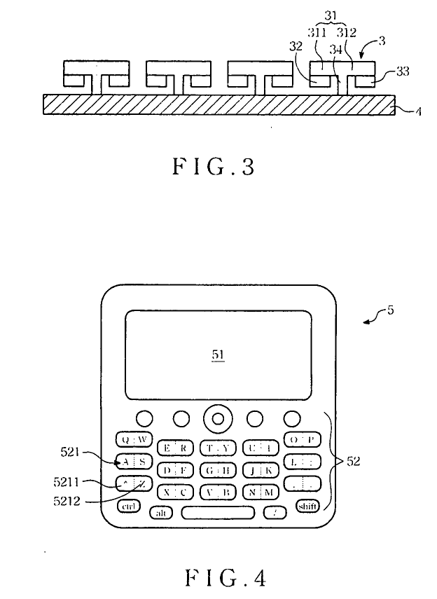

Refer to FIG. 4, which illustrates a schematic diagram of a PDA or a mobile phone applied with the keypad of the present invention. The PDA in FIG. 4 comprises a main body 5, a display panel 51 and a keypad 52. The display panel 51 and the keypad 52 are set on a surface of the main body 5. The keypad 52 comprises a plurality of keys 521, and each of the keys 521 further comprises a first pressing region 5211 and a second pressing region 5212 on the exposed surface. The first pressing region 5211 and the second pressing region 5212 represent different letters. That is, each key 521 may represent two alphabets. The two pressing regions 5211, 5212 on each key 521 can not be pressed at the same time due to the existence of the prop (not shown in the figure). Therefore, the keypad 52 of the present invention can obviously provide effective dual-mode keys.

The present invention provides an effective dual-mode keypad to solve problems mentioned in prior art. The dual-mode keypad may decrease the numbers of keys thereof, so that the present keypad can help to develop an electronic device having a more compact size.

Furthermore, the interior elements of the keypad module of the present invention can be variable to meet different electronic devices. For instance, the prop 34 in FIG. 3 is formed as a whole with the key 31. In another embodiment, the prop can be a frame to be assembled onto the key 31 for integrally performing a seesaw motion therearound.

To sum up, the present keypad module with a dual-mode function is suitable for various electronic devices. By providing the keypad of the present invention, not only the size of the keypad can be reduced, but also the cost of the keypad can be reduced by comparing with the conventional electronic device having a touch pad.

While the present invention has been particularly shown and described with reference to such preferred embodiments, it will be understood by those skilled in the art that various changes in form and detail may be without departing from the spirit and scope of the present invention.

What is claimed is:

1. A keypad module comprising:
a plurality of keys, each of the keys having a first pressing region and a second pressing region on an exposed surface thereof, the first pressing region and the second pressing being arranged symmetrically to each other;
a first receiver disposed under the first pressing region for generating a first signal while the first pressing region being pressed;
a second receiver disposed under the second pressing region for generating a second signal while the second receiver region being pressed; and
a prop disposed between the first receiver and the second receiver for ensuring only one of the first pressing region and the second pressing region is pressed at a time.

2. The keypad module of claim 1, wherein the first receiver is made of an elastomer.

3. The keypad module of claim 1, wherein the second receiver is made of an elastomer.

4. The keypad module of claim 1, wherein the prop and the plurality of keys are formed as a whole.

5. An electronic device having a main body, a display panel and a keypad module, wherein the display panel and the keypad module are set on a surface of the main body, the keypad module comprising:
a plurality of keys, each of the keys having a first pressing region and a second pressing region on an exposed surface thereof, the first pressing region and the second pressing being arranged symmetrically to each other;
a first receiver disposed under the first pressing region for generating a first signal while the first pressing region being pressed;
a second receiver disposed under the second pressing region for generating a second signal while the second receiver region being pressed; and
a prop disposed between the first receiver and the second receiver for ensuring only one of the first pressing region and the second pressing region is pressed at a time.

6. The electronic device of claim 5, wherein the first receiver is made of an elastomer.

7. The electronic device of claim 5, wherein the second receiver is made of an elastomer.

8. The electronic device of claim 5, wherein the electronic device is a mobile phone.

9. The electronic device of claim 5, wherein the electronic device is a personal digital assistant (PDA).

10. The electronic device of claim 5, wherein the prop and the plurality of keys are formed as a whole.
